(19) United States
(12) Patent Application Publication
(10) Pub. No.: US 2022/0069143 A1
(43) Pub. Date: Mar. 3, 2022

(54) OPTICAL RECEIVER MODULE

(71) Applicant: Mitsubishi Electric Corporation, Tokyo (JP)

(72) Inventor: Kazuki YAMAJI, Tokyo (JP)

(73) Assignee: Mitsubishi Electric Corporation, Tokyo (JP)

(21) Appl. No.: 17/522,559

(22) Filed: Nov. 9, 2021

Related U.S. Application Data
(63) Continuation of application No. PCT/JP2019/023313, filed on Jun. 12, 2019.

(51) Int. Cl. H01L 31/02; H01L 31/107

(52) U.S. Cl. CPC H01L 31/02027; H01L 31/107; H01L 31/02005

(57) ABSTRACT

Output terminals of a TIA and front electrodes of dielectric substrates are electrically connected by wires, output lead pins and the front electrodes are electrically connected by wires, and output signals of the TIA are outputted, via the dielectric substrates, to the output lead pins.

### CROSS REFERENCE TO RELATED APPLICATION

This application is a Continuation of PCT International Application No. PCT/JP2019/023313, filed on Jun. 12, 2019, which is hereby expressly incorporated by reference into the present application.

### TECHNICAL FIELD

The present disclosure relates to an optical receiver module.

### BACKGROUND ART

In optical receiver modules in CAN packages, a light signal received by a semiconductor light receiving element is converted into an electric signal, and the electric signal is amplified by a transimpedance amplifier (described as a TIA hereinafter) and is outputted, via lead pins, to outside the modules.

In a conventional optical receiver modules in a CAN package, typically, electric wiring between parts in the module and between parts and lead pins is performed by bonding wires (for example, refer to Patent Literature 1).

### CITATION LIST

### Patent Literature

Patent Literature 1: JP 2012-138601 A

### SUMMARY OF INVENTION

### Technical Problem

There is a problem with conventional optical receiver modules in CAN packages that as the frequency of a signal increases, the inductance components of wires have higher impedance, and the band degrades.

Particularly in an optical receiver module described in Patent Literature 1, because the distances between lead pins and TIA output terminals are long, the wires connecting the TIA output terminals and the lead pins are long and the degradation in the band is significant.

The present disclosure is made to solve the above problem, and it is therefore an object of the present disclosure to obtain an optical receiver module whose band is improved.

### Solution to Problem

An optical receiver module according to present disclosure includes: a stem; a semiconductor light receiving element to convert a light signal into an electric signal; a transimpedance amplifier to amplify the electric signal; a pair of output lead pins via which differential output signals of the transimpedance amplifier are taken to outside the stem; dielectric substrates disposed between output terminals of the transimpedance amplifier and the output lead pins; and first electrodes disposed on first surfaces of the dielectric substrates. The output terminals of the transimpedance amplifier and the first electrodes are electrically connected by wires. The output lead pins and the first electrodes are electrically connected by wires. The output signals of the transimpedance amplifier are outputted, via the dielectric substrates, to the output lead pins. The optical receiver module further comprises second electrodes disposed on second surfaces opposite to the first surfaces of the dielectric substrates. Each of the first electrodes is divided into multiple electrode regions. One of the multiple electrode regions is electrically connected to one of the second electrodes by a through via or a lateral electrode. The electrode region electrically connected to the one of the second electrodes and a ground terminal of the transimpedance amplifier are electrically connected by a wire.

### Advantageous Effects of Invention

According to the present disclosure, the output terminals of the TIA and the first electrodes of the dielectric substrates are electrically connected by wires, the output lead pins and the first electrodes are electrically connected by wires, and the output signals of the TIA are outputted, via the dielectric substrates, to the output lead pins. As a result, because the inductances of the wires are reduced and the pass band is widened, the band is improved.

### BRIEF DESCRIPTION OF DRAWINGS

FIG. 1A is a top view showing the structure of an optical receiver module according to Embodiment 1;

FIG. 1B is a partial cross sectional view showing the structure of the optical receiver module of FIG. 1A;

FIG. 2A is a top view showing the structure of a conventional optical receiver module;

FIG. 2B is a partial cross sectional view showing the structure of the optical receiver module of FIG. 2A;

FIG. 3A is a diagram showing an equivalent circuit of the optical receiver module according to Embodiment 1;

FIG. 3B is a diagram showing an equivalent circuit of the conventional optical receiver module;

FIG. 4 is a diagram showing a simulation result of pass characteristics;

FIG. 5A is a top view showing the structure of an optical receiver module according to Embodiment 2;

FIG. 5B is a perspective view showing a dielectric substrate in Embodiment 2;

FIG. 6A is a top view showing the structure of an optical receiver module according to Embodiment 3;

FIG. 6B is a perspective view showing a dielectric substrate in Embodiment 3;

FIG. 6C is a perspective view showing another example of the dielectric substrate in Embodiment 3;

FIG. 7A is a top view showing the structure of an optical receiver module according to Embodiment 4;

FIG. 7B is a perspective view showing a dielectric substrate in Embodiment 4;

FIG. 7C is a perspective view showing another example of the dielectric substrate in Embodiment 3;

FIG. 8 is a diagram showing an equivalent circuit of the optical receiver module according to Embodiment 4;

FIG. 9 is a diagram showing a simulation result of pass characteristics;

FIG. 10A is a top view showing the structure of an optical receiver module according to Embodiment 5;

FIG. 10B is a perspective view showing a dielectric substrate in Embodiment 5;

FIG. 11 is a diagram showing an equivalent circuit of the optical receiver module according to Embodiment 5;

FIG. 12 is a diagram showing a simulation result of pass characteristics;

FIG. 13A is a top view showing the structure of an optical receiver module according to Embodiment 6;

FIG. 13B is a perspective view showing a dielectric substrate in Embodiment 6;

FIG. 13C is a perspective view showing another example of the dielectric substrate in Embodiment 6;

FIG. 14 is a diagram showing an equivalent circuit of the optical receiver module according to Embodiment 6;

FIG. 15 is a diagram showing a simulation result of pass characteristics;

FIG. 16A is a top view showing the structure of an optical receiver module according to Embodiment 7;

FIG. 16B is a perspective view showing a dielectric substrate in Embodiment 7;

FIG. 17 is a diagram showing an equivalent circuit of the optical receiver module according to Embodiment 7; and

FIG. 18 is a diagram showing a simulation result of pass characteristics.

### DESCRIPTION OF EMBODIMENTS

### Embodiment 1

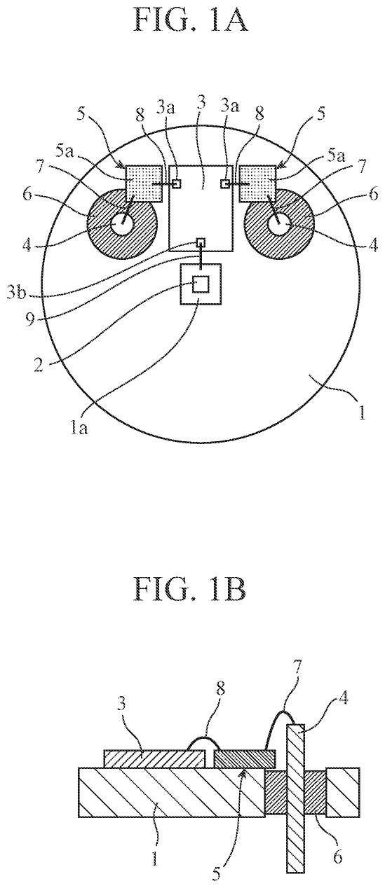

FIG. 1A is a top view showing the structure of an optical receiver module according to Embodiment 1, and schematically shows a structure on a stem 1 with the cap of a CAN package removed. FIG. 1B is a partial cross sectional view showing the structure of the optical receiver module of FIG. 1A, and shows a partial cross section in the vicinity of an output lead pin 4. The optical receiver module shown in FIG. 1A is a module in the CAN package in which a submount 1a is mounted on the stem 1 and a semiconductor light receiving element 2 is mounted on the submount 1a. The semiconductor light receiving element 2 converts a light signal received into an electric signal.

A transimpedance amplifier (TIA) 3 amplifies the electric signal outputted from the semiconductor light receiving element 2. For example, the TIA 3 includes a pair of output terminals 3a and an input terminal 3b, and performs differential amplification on the electric signal inputted, via the input terminal 3b, from the semiconductor light receiving element 2 and outputs the amplified signals from the output terminals 3a. A pair of output lead pins 4 is one from which the differential output signals from the TIA 3 are taken to outside the stem 1.

The pair of output lead pins 4 penetrates the stem 1 and projects vertically above and below the stem 1, and the gap between the stem 1 and each of the output lead pins 4 is filled with a sealing agent 6, as shown in FIG. 1B. The output lead pins 4 are fixed to the stem 1 in a state where each of the output lead pins is insulated from the stem 1 by the sealing agent 6.

Dielectric substrates 5 are disposed between the output terminals 3a of the TIA 3 and the output lead pins 4. For the dielectric substrates 5, for example, glass, alumina (Al₂O₃), or aluminum nitride (AlN) is used as a dielectric material. A front electrode (first electrode) 5a is disposed on a front surface (first surface) of each of the dielectric substrates 5, as shown in FIG. 1A. Further, a rear electrode (second electrode) is disposed on the whole of a surface (rear surface, second surface) opposite to the front surface of each of the dielectric substrates 5.

The output lead pins 4 and the front electrodes 5a are electrically connected by wires 7, and the output terminals 3a of the TIA 3 and the front electrodes 5a are electrically connected by wires 8. The semiconductor light receiving element 2 and the input terminal 3b of the TIA 3 are electrically connected by a wire 9.

The stem 1 practically includes external terminals in addition to the output lead pins 4. For example, there is a lead pin for supplying electric power from outside the stem 1 to both the semiconductor light receiving element 2 and the TIA 3. Although this lead pin is omitted in the illustrations in FIGS. 1A and 1B, the lead pin penetrates the stem 1 and projects vertically above and below the stem 1, and is fixed to the stem 1 in a state where the gap between the lead pin and the stem 1 is filled with a sealing agent, like the output lead pins 4. Further, a ground pin is disposed on a rear surface of the stem 1 (a surface opposite to the mounting surface shown in FIG. 1A). The ground pin is a ground terminal for electrically connecting the stem 1 to a ground outside the stem.

As the semiconductor light receiving element 2, a semiconductor light receiving element of the frontside or backside incidence type can be used. For example, in a case where the semiconductor light receiving element 2 is of the front-side incidence type, an anode electrode is disposed on an incidence surface, a cathode electrode is disposed on a rear surface which is a surface opposite to the incidence surface, and the cathode electrode is disposed on the submount 1a using a conductive material such as a solder or an electrically conductive adhesive. The anode electrode of the semiconductor light receiving element 2 and the input terminal 3b of the TIA 3 are electrically connected by a wire 9, the cathode electrode of the semiconductor light receiving element 2 is electrically connected to a front electrode of the submount 1a, and this front electrode is electrically connected to a power supply circuit by a wire.

In a case where the semiconductor light receiving element 2 is of the backside incidence type, an anode electrode and a cathode electrode are disposed on a surface (rear surface) opposite to an incidence surface, and are flip-chip mounted in such a way that the anode and cathode electrodes are electrically connected to pads on the submount 1a which correspond to the anode and cathode electrodes. The pad connected to the anode electrode is electrically connected to the input terminal 3b of the TIA 3 by a wire 9, and the pad connected to the cathode electrode is electrically connected to a power supply circuit by a wire.

As the semiconductor light receiving element 2, a photodiode or an avalanche photodiode can be used. For example, the semiconductor light receiving element 2 may be a flip-chip-mounted photodiode of the backside incidence type or a flip-chip-mounted avalanche photodiode of the backside incidence type.

Next, the operation of the optical receiver module according to Embodiment 1 will be explained.

The semiconductor light receiving element 2 receives a light signal which, for example, propagates through an optical fiber and is condensed by a lens, and converts the light signal into an electric signal. The electric signal converted from the light signal is converted by the semiconductor light receiving element 2 is inputted, via the wire 9 and the input terminal 3b, to the TIA 3.

The TIA 3 performs differential amplification on the inputted electric signal, and outputs the amplified electric signals as differential output signals from the output terminals 3a. The differential output signals are outputted, via the wires 8, to the front electrodes 5a of the dielectric substrates 5, are outputted from the front electrodes 5a, via the wires 7, to the output lead pins 4, and are taken, via the output lead pins 4, to outside the stem 1. That is, the output signals of the TIA 3 are outputted, via the dielectric substrates 5, to the output lead pins 4.

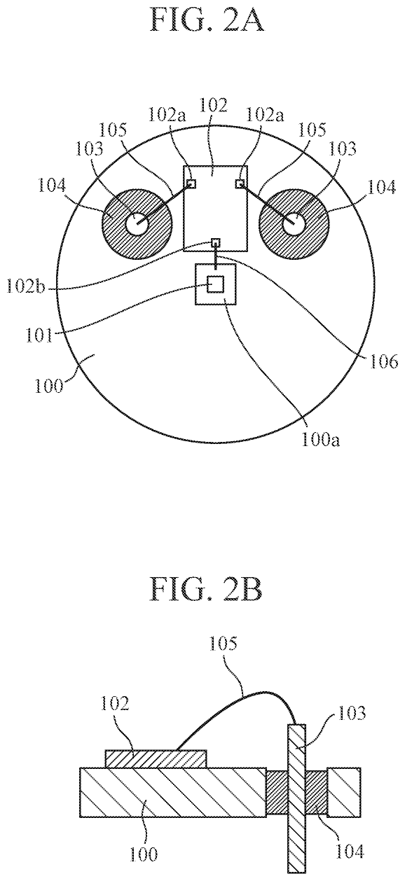

Next, a conventional optical receiver module which is an object to be compared with the optical receiver module according to Embodiment 1 will be explained. FIG. 2A is a top view showing the structure of the conventional optical receiver module, and schematically shows a structure on a stem 100 with the cap of a CAN package removed, like FIG. 1A. FIG. 2B is a partial cross sectional view showing the structure of the optical receiver module of FIG. 2A, and shows a partial cross section in the vicinity of an output lead pin 103. The optical receiver module shown in FIG. 2A is a module in the CAN package in which a submount 100a is mounted on the stem 100 and a semiconductor light receiving element 101 is mounted on the submount 100a.

A TIA 102 includes a pair of output terminals 102a and an input terminal 102b, and performs differential amplification on an electric signal inputted, via the input terminal 102b, from the semiconductor light receiving element 101, and outputs the electric signals from the output terminals 102a. A pair of output lead pins 103 penetrates the stem 100 and projects vertically above and below the stem 100, and the gap between the stem 100 and each of the output lead pins 103 is filled with a sealing agent 104, as shown in FIG. 2B. The output lead pins 103 are fixed to the stem 100 in a state where each of the output lead pins is insulated from the stem 100 by the sealing agent 104.

The output terminals 102a of the TIA 102 and the output lead pins 103 are electrically connected by wires 105, and the semiconductor light receiving element 101 and the input terminal 102b of the TIA 102 are electrically connected by a wire 106. The electric signals on which the differential amplification is performed by the TIA 102 are outputted from the output terminals 102a, via the wires 105, to the output lead pins 103, and are taken, via the output lead pins 103, to outside the stem 100.

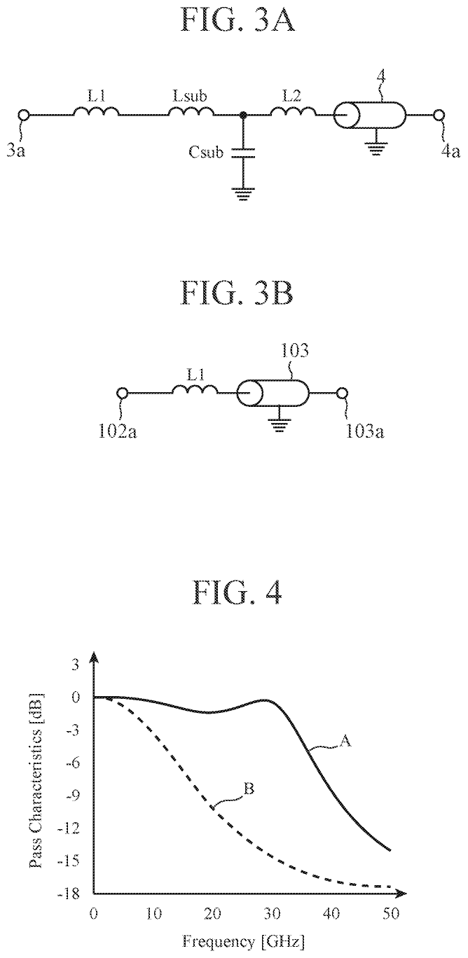

FIG. 3A is a diagram showing an equivalent circuit of the optical receiver module according to Embodiment 1, and shows the equivalent circuit of the optical receiver module shown in FIGS. 1A and 1B. FIG. 3B is a diagram showing an equivalent circuit of the conventional optical receiver module, and shows the equivalent circuit of the optical receiver module shown in FIGS. 2A and 2B. In the conventional optical receiver module, because no dielectric substrates are provided in sections from the lead pin outputs 103a of the output lead pins 103 to points where the output signals are outputted, the equivalent circuit becomes one in which only inductances L1 of the wires 105 occur, as shown in FIG. 3B.

In contrast with this, in the optical receiver module according to Embodiment 1, the output signals of the TIA 3 are outputted, via the dielectric substrates 5, to the output lead pins 4, and are outputted from lead pin outputs 4a. Therefore, inductances L1 of the wires 8, inductances L_{sub} of the dielectric substrates 5, and inductances L2 of the wires 7 occur between the output terminals 3a of the TIA 3 and the output lead pins 4, as shown in FIG. 3A. In addition, because the dielectric substrates 5 have capacitivity, capacitances C_{sub} of the dielectric substrates 5 occur.

FIG. 4 is a diagram showing simulation results of pass characteristics, and a simulation result of the optical receiver module according to Embodiment 1 is denoted by a reference sign A and a simulation result of the conventional optical receiver module is denoted by a reference sign B. In the conventional optical receiver module, the TIA 102 and each of the output lead pins 103 are apart from each other, and the wires 105 are long. Therefore, the inductance component of each of the wires 105 has higher impedance as the frequency of the signals increases, and the band degrades as shown by the simulation result B.

In contrast, in the optical receiver module according to Embodiment 1, the output signals of the TIA 3 are outputted to the output lead pins 4 after being transmitted via the dielectric substrates 5. Therefore, although the inductances L1, L_{sub}, and L2 occur, the wires 8 between the output terminals 3a of the TIA 3 and the dielectric substrates 5 can be shortened, and the wires 7 between the dielectric substrates 5 and the output lead pins 4 can also be shortened. As a result, the inductances L1 and L2 can be reduced. In the simulation result A, the inductances and the capacitances cause peaking to occur, thereby widening the pass band to close to the frequency of 30 GHz.

As described above, in the optical receiver module according to Embodiment 1, the output terminals 3a of the TIA 3 and the front electrodes 5a of the dielectric substrates 5 are electrically connected by the wires 8, the output lead pins 4 and the front electrodes 5a are electrically connected by the wires 7, and the output signals of the TIA 3 are outputted, via the dielectric substrates 5, to the output lead pins 4. The reduction of the inductances of the wires and the insertion of the capacitive components of the dielectric substrates 5 provide an improvement in the band.

### Embodiment 2

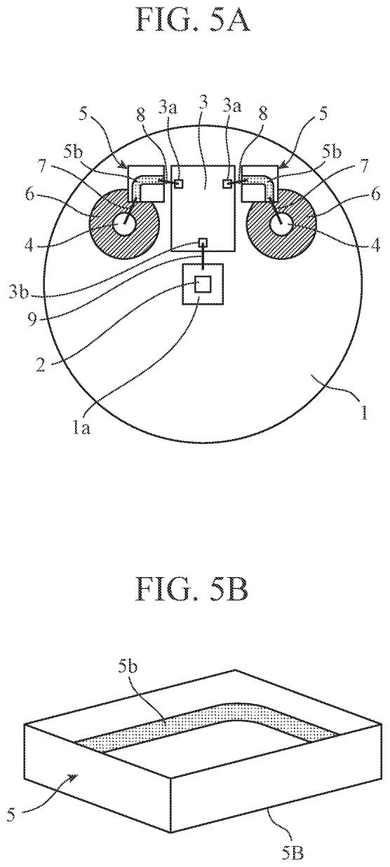

FIG. 5A is a top view showing the structure of an optical receiver module according to Embodiment 2, and schematically shows a structure on a stem 1 with the cap of a CAN package removed. FIG. 5B is a perspective view showing a dielectric substrate 5 in Embodiment 2. The optical receiver module according to Embodiment 2 has the same basic structure as the optical receiver module according to Embodiment 1, but differs from the optical receiver module according to Embodiment 1 in that each of dielectric substrates 5 has a front electrode 5b, as shown in FIG. 5A.

The front electrode 5b is a first electrode which is disposed on a front surface (first surface) of each of the dielectric substrates 5 in Embodiment 2, and whose electrode width is set in such a way that its characteristic impedance is 50Ω. Further, a rear electrode (second electrode) 5B is disposed on a rear surface (second surface) of each of the dielectric substrates 5.

As mentioned above, in the optical receiver module according to Embodiment 2, each of the dielectric substrates 5 has the front electrode 5b whose characteristic impedance is 50Ω. For either each output terminal 3a of a TIA 3 or a next-stage circuit which receives output signals of the optical receiver module, design is typically performed in such a way that its characteristic impedance is 50Ω. Therefore, reflection caused by an impedance mismatch with the next-stage circuit which receives the output signals transmitted via the front electrodes 5b is reduced.

### Embodiment 3

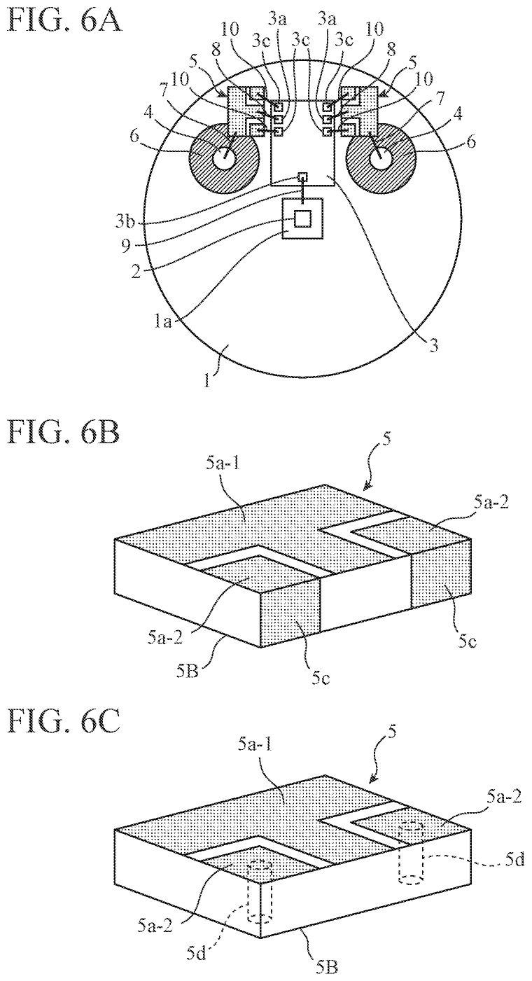

FIG. 6A is a top view showing the structure of an optical receiver module according to Embodiment 3, and schematically shows a structure on a stem 1 with the cap of a CAN package removed. FIG. 6B is a perspective view showing a dielectric substrate 5 in Embodiment 3. Further, FIG. 6C is a perspective view showing another example of the dielectric substrate 5 in Embodiment 3. As shown in FIG. 6A, in each of dielectric substrates 5 in the optical receiver module according to Embodiment 3, a front electrode is divided into multiple electrode regions.

A TIA 3 in Embodiment 3 includes a pair of output terminals 3a, an input terminal 3b, and two pairs of ground terminals 3c, performs differential amplification on an electric signal inputted, via the input terminal 3b, from a semiconductor light receiving element 2, and outputs the amplified electric signals from the output terminals 3a. As shown in FIGS. 6B and 6C, an electrode region 5a-1 and two electrode regions 5a-2 are disposed on a front surface (first surface) of each of the dielectric substrates 5, and a rear electrode (second electrode) 5B is disposed on the whole of a rear surface (second surface) of each of the dielectric substrates 5. The rear electrode 5B is grounded in a state where each of the dielectric substrates 5 is mounted on the stem 1.

Further, the electrode regions 5a-2 of each of the dielectric substrates 5 are electrically connected to the rear electrode 5B by lateral electrodes 5c, as shown in FIG. 6B. The lateral electrodes 5c are formed by, for example, metallizing a side surface of each of the dielectric substrates 5, and have a length corresponding to the thickness of each of the dielectric substrates 5. The electrode regions 5a-2 and the rear electrode 5B may be electrically connected by through vias 5d, as shown in FIG. 6C. The through vias 5d are holes penetrating from the front surface to the rear surface of each of the dielectric substrates 5, and the inner surfaces of the through vias are metallized. The electrode regions 5a-2 and the rear electrode 5B are electrically connected by the through vias 5d.

An output lead pin 4 and the electrode region 5a-1 of each of the dielectric substrates 5 are electrically connected by a wire 7. An output terminal 3a of the TIA 3 and the electrode region 5a-1 of each of the dielectric substrates 5 are electrically connected by a wire 8. The semiconductor light receiving element 2 and the input terminal 3b of the TIA 3 are electrically connected by a wire 9. Ground terminals 3c of the TIA 3 and the electrode regions 5a-2 of each of the dielectric substrates 5 are electrically connected by wires 10.

An electric signal converted from a light signal by the semiconductor light receiving element 2 is inputted, via the wire 9 and the input terminal 3b, to the TIA 3. The TIA performs differential amplification on the inputted electric signal and outputs the amplified electric signals as differential output signals from the output terminals 3a. The differential output signals are outputted, via the wires 8, to the electrode regions 5a-1 of the dielectric substrates 5, are outputted from the electrode regions 5a-1, via the wires 7, to the output lead pins 4, and are taken, via the output lead pins 4, to outside the stem 1. That is, the output signals of the TIA 3 are outputted, via the dielectric substrates 5, to the output lead pins 4.

As mentioned above, in the optical receiver module according to Embodiment 3, the electrode regions 5a-2 which each of the dielectric substrates 5 has are electrically connected to the rear electrode 5B by the lateral electrodes 5c or the through vias 5d, and the electrode regions 5a-2 are electrically connected to ground terminals 3c of the TIA 3 by wires 10. The rear electrode 5B is grounded to the stem 1. In the optical receiver module according to Embodiment 3, a part of a path from each of the ground terminals 3c to the stem 1, the part corresponding to the thickness of each of the dielectric substrates 5, is replaced by either a lateral electrode 5c or a through via 5d having a smaller inductance than wires. Therefore, the inductances of the wires are reduced, and the grounding of the TIA 3 can be enhanced.

### Embodiment 4

In an optical receiver module according to Embodiment 4, a front electrode of each of dielectric substrates 5 is divided into electrode regions including an electrode region through which an output signal propagates, and electrode regions grounded, and the electrode region through which an output signal propagates and an electrode region grounded are electrically connected by a capacitive element.

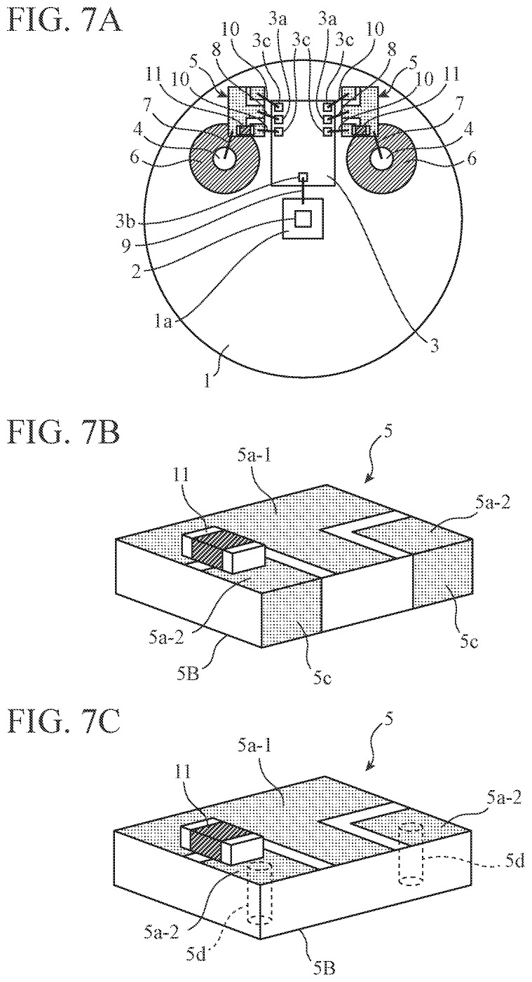

FIG. 7A is a top view showing the structure of the optical receiver module according to Embodiment 4, and schematically shows a structure on a stem 1 with the cap of a CAN package removed. FIG. 7B is a perspective view showing a dielectric substrate 5 in Embodiment 4. Further, FIG. 7C is a perspective view showing another example of the dielectric substrate 5 in Embodiment 4.

A TIA 3 in Embodiment 4 includes a pair of output terminals 3a, an input terminal 3b, and two pairs of ground terminals 3c, performs differential amplification on an electric signal inputted, via the input terminal 3b, from a semiconductor light receiving element 2, and outputs the amplified electric signals from the output terminals 3a, like that of Embodiment 3. As shown in FIGS. 7B and 7C, an electrode region 5a-1 and two electrode regions 5a-2 are disposed on a front surface (first surface) of each of dielectric substrates 5, and a rear electrode (second electrode) 5B is disposed on the whole of a rear surface (second surface). The rear electrode 5B is grounded in a state where each of the dielectric substrates 5 is mounted on the stem 1.

The electrode regions 5a-2 of each of the dielectric substrates 5 are electrically connected to the rear electrode 5B by lateral electrodes 5c, as shown in FIG. 7B. Further, the electrode regions 5a-2 and the rear electrode 5B may be electrically connected by through vias 5d, as shown in FIG. 7C. The lateral electrodes 5c or the through vias 5d are the same as those explained in Embodiment 3.

A chip capacitor 11 is a capacitive element which is mounted on the front surface of each of the dielectric substrates 5, and which electrically connects between the electrode region 5a-1 and one of the two electrode regions 5a-2. For example, the chip capacitor 11 is mounted on the front surface of each of the dielectric substrates 5, using a conductive substance such as a solder or an electrically conductive adhesive.

An output lead pin 4 and the electrode region 5a-1 of each of the dielectric substrates 5 are electrically connected by a wire 7, like those of Embodiment 3. An output terminal 3a of the TIA 3 and the electrode region 5a-1 of each of the dielectric substrates 5 are electrically connected by a wire 8. The semiconductor light receiving element 2 and the input terminal 3b of the TIA 3 are electrically connected by a wire 9. Ground terminals 3c of the TIA 3 and the electrode regions 5a-2 of each of the dielectric substrates 5 are electrically connected by wires 10.

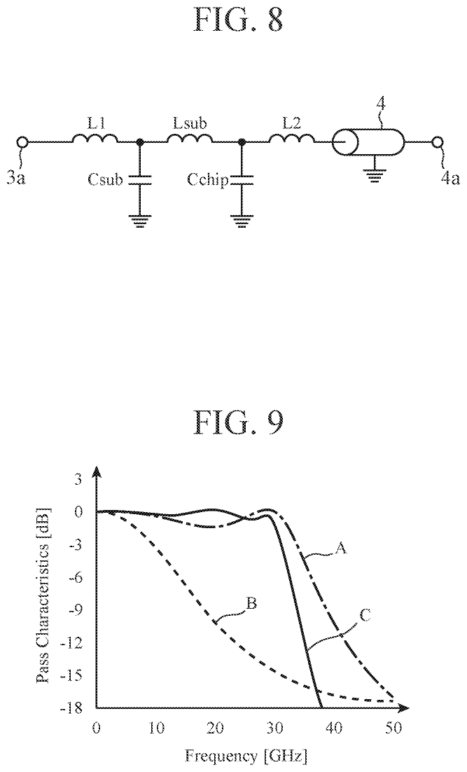

FIG. 8 is a diagram showing an equivalent circuit of the optical receiver module according to Embodiment 4, and shows the equivalent circuit of the optical receiver module shown in FIG. 7A. In the optical receiver module according to Embodiment 4, output signals of the TIA 3 are outputted, via the electrode regions 5a-1, to the output lead pins 4, and are outputted from lead pin outputs 4a. Each of the electrode regions 5a-1 is electrically connected to an electrode region 5a-2 by a chip capacitor 11. The electrode region 5a-2 is electrically connected to the rear electrode 5B by a lateral electrode 5c or a through via 5d, and is grounded.

Between the output terminals 3a of the TIA 3 and the output lead pins 4, inductances L1 of the wires 8, inductances L_{sub} of the dielectric substrates 5, and inductances L2 of the wires 7 occur, as shown in FIG. 8. Because the dielectric substrates 5 have capacitivity, capacitances C_{sub} of the dielectric substrates 5 occur and capacitances C_{chip} of the chip capacitors 11 are further added. That is, the optical receiver module according to Embodiment 4 has a structure in which one stage of low pass filter which includes an inductance and a capacitance is added to the optical receiver module according to Embodiment 1.

FIG. 9 is a diagram showing simulation results of pass characteristics, and a simulation result of the optical receiver module according to Embodiment 1 is denoted by a reference sign A and a simulation result of a conventional optical receiver module is denoted by a reference sign B. In addition, a simulation result of the optical receiver module according to Embodiment 4 is denoted by a reference sign C. The conventional optical receiver module has the same structure as that shown in FIGS. 2A and 2B.

In the optical receiver module according to Embodiment 4, because the output signals of the TIA 3 are outputted to the output lead pins 4 after being transmitted via the dielectric substrates 5, the inductances L1 and L2 can be reduced. Further, because a low pass filter which includes an inductor and a capacitor is added, while in the simulation result C, peaking causes the pass band to be widened to close to the frequency of 30 GHz, an attenuation characteristic steeper than that in the simulation result A is provided in a high frequency band.

As mentioned above, in the optical receiver module according to Embodiment 4, the electrode regions 5a-2 which each of the dielectric substrates 5 has are electrically connected to the rear electrode 5B by the lateral electrodes 5c or the through vias 5d, and one of the two electrode regions 5a-2 is electrically connected to the electrode region 5a-1 by a chip capacitor 11. The rear electrode 5B is grounded to the stem 1.

Because a low pass filter which includes an inductance and a capacitance is added in the optical receiver module according to Embodiment 4, the band is improved, like in the case of any one of Embodiments 1 to 3. In addition, because an attenuation characteristic steeper than that of the optical receiver module according to Embodiment 1 is provided in a high frequency band, noises in the high frequency band can be eliminated.

### Embodiment 5

In each of dielectric substrates 5 of an optical receiver module according to Embodiment 5, a front electrode is divided into two electrode regions, and the electrode regions are electrically connected by an inductive element.

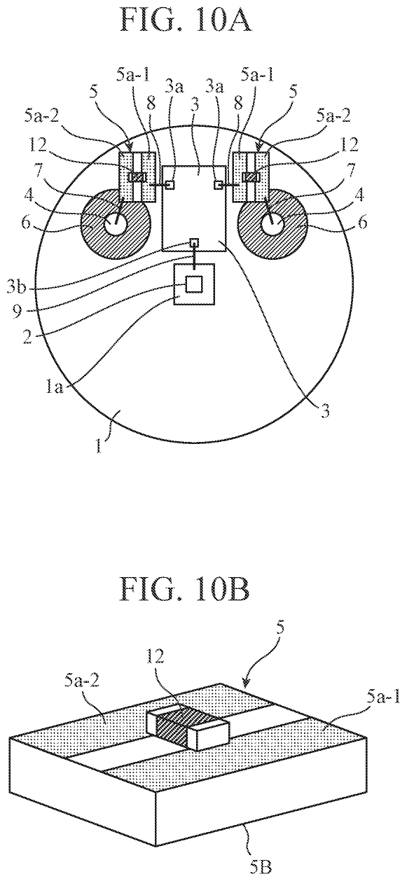

FIG. 10A is a top view showing the structure of the optical receiver module according to Embodiment 5, and schematically shows a structure on a stem 1 with the cap of a CAN package removed. FIG. 10B is a perspective view showing a dielectric substrate 5 in Embodiment 5.

A TIA 3 in Embodiment 5 includes a pair of output terminals 3a and an input terminal 3b, as shown in FIG. 10A, and performs differential amplification on an electric signal inputted, via the input terminal 3b, from a semiconductor light receiving element 2, and outputs the amplified electric signals from the output terminals 3a. As shown in FIGS. 10A and 10B, one electrode region 5a-1 and one electrode region 5a-2 are disposed on a front surface (first surface) of each of the dielectric substrates 5, and a rear electrode (second electrode) 5B is disposed on the whole of a rear surface (second surface). The rear electrode 5B is grounded in a state where each of the dielectric substrates 5 is mounted on the stem 1.

A chip inductor 12 is an inductive element which is mounted on the front surface of each of the dielectric substrates 5, and which electrically connects the electrode region 5a-1 and the electrode region 5a-2. The chip capacitor 12 is mounted on the front surface of each of the dielectric substrates 5, using, for example, a conductive substance such as a solder or an electrically conductive adhesive. Output lead pins 4 and the electrode regions 5a-2 of the dielectric substrates 5 are electrically connected by wires 7. The output terminals 3a of the TIA 3 and the electrode regions 5a-1 of the dielectric substrates 5 are electrically connected by wires 8. The semiconductor light receiving element 2 and the input terminal 3b of the TIA 3 are electrically connected by a wire 9.

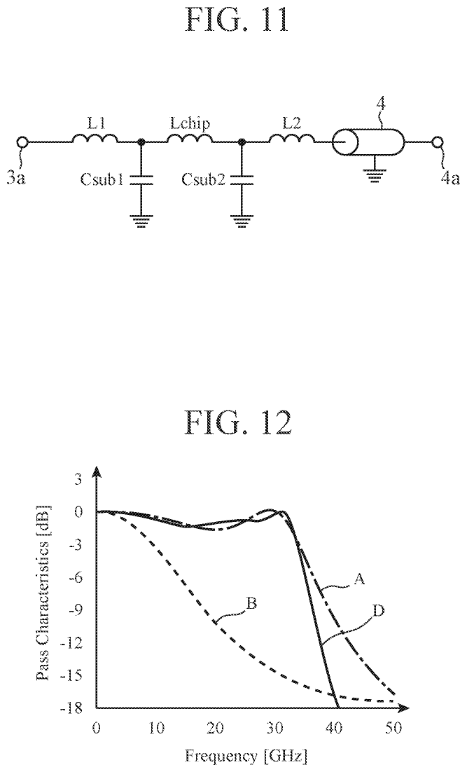

FIG. 11 is a diagram showing an equivalent circuit of the optical receiver module according to Embodiment 5, and shows the equivalent circuit of the optical receiver module shown in FIG. 10A. In the optical receiver module according to Embodiment 5, output signals of the TIA 3 are outputted, via the electrode regions 5a-1, the chip inductors 12, and the electrode regions 5a-2, to the output lead pins 4, and are outputted from lead pin outputs 4a. Between the output terminals 3a of the TIA 3 and the output lead pins 4, inductances L1 of the wires 8, inductances L_{chip} of the chip inductors 12, and inductances L2 of the wires 7 occur, as shown in FIG. 11.

In each of the dielectric substrates 5, a capacitance C_{sub1} occurs between the electrode region 5a-1 and the rear electrode 5B, and a capacitance C_{sub2} occurs between the electrode region 5a-2 and the rear electrode 5B. That is, the optical receiver module according to Embodiment 5 has a structure in which one stage of low pass filter which includes an inductance and a capacitance is added, like the optical receiver module according to Embodiment 4.

FIG. 12 is a diagram showing simulation results of pass characteristics, and a simulation result of the optical receiver module according to Embodiment 1 is denoted by a reference sign A and a simulation result of a conventional optical receiver module is denoted by a reference sign B. In addition, a simulation result of the optical receiver module according to Embodiment 5 is denoted by a reference sign D. The conventional optical receiver module has the same structure as that shown in FIGS. 2A and 2B.

In the optical receiver module according to Embodiment 5, because the output signals of the TIA 3 are outputted to the output lead pins 4 after being transmitted via the dielectric substrates 5, the inductances L1 and L2 can be reduced. Further, because the low pass filter which includes an inductance and a capacitance is added, in the simulation result D, peaking causes the pass band to be widened to close to the frequency of 30 GHz, and an attenuation characteristic steeper than that in the simulation result A is provided in a high frequency band.

As mentioned above, in the optical receiver module according to Embodiment 5, the electrode region 5a-1 and the electrode region 5a-2 of each of the dielectric substrates 5 are electrically connected by a chip inductor 12. Because in the optical receiver module according to Embodiment 5 a low pass filter that includes an inductance and a capacitance is added, the band is improved, like in the case of any one of Embodiments 1 to 4. In addition, because an attenuation characteristic steeper than that of the optical receiver module according to Embodiment 1 is provided in a high frequency band, noises in the high frequency band can be eliminated.

### Embodiment 6

In an optical receiver module according to Embodiment 6, a front electrode of each of dielectric substrates 5 is divided into multiple electrode regions including an electrode region through which an output signal propagates, and electrode regions grounded, and the electrode region through which an output signal propagates and the electrode regions grounded are electrically connected by capacitive elements. The electrode region through which an output signal propagates is formed by, for example, a pattern extending, as a whole, in one direction while extending to form a zigzag pattern.

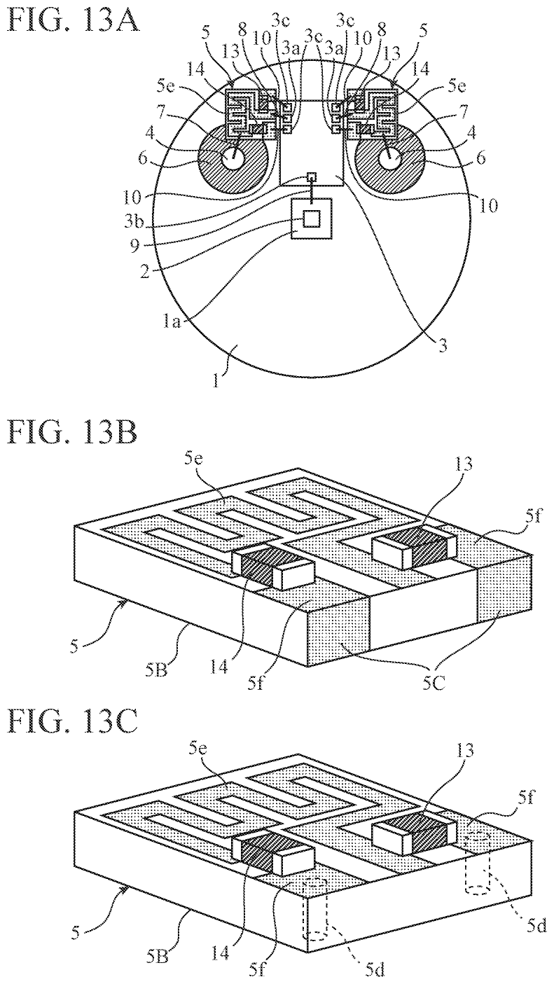

FIG. 13A is a top view showing the structure of the optical receiver module according to Embodiment 6, and schematically shows a structure on a stem 1 with the cap of a CAN package removed. FIG. 13B is a perspective view showing a dielectric substrate 5 in Embodiment 6. FIG. 13C is a perspective view showing another example of the dielectric substrate 5 in Embodiment 6.

A TIA 3 in Embodiment 6 includes a pair of output terminals 3a, an input terminal 3b, and two pairs of ground terminals 3c, as shown in FIG. 13A, and performs differential amplification on an electric signal inputted, via the input terminal 3b, from a semiconductor light receiving element 2, and outputs the amplified electric signals from the output terminals 3a. As shown in FIGS. 13B and 13C, an electrode region 5e and two electrode regions 5f are disposed on a front surface (first surface) of each of the dielectric substrates 5, and a rear electrode (second electrode) 5B is disposed on the whole of a rear surface (second surface). The rear electrode 5B is grounded in a state where each of the dielectric substrates 5 is mounted on the stem 1.

Further, the electrode region 5e has a pattern extending, as a whole, in one direction while extending to form a zigzag pattern, and an output signal from the TIA 3 propagates through the electrode region. The two electrode regions 5f are electrically connected to the rear electrode 5B by lateral electrodes 5c, as shown in FIG. 13B. The electrode regions 5f and the rear electrode 5B may be electrically connected by through vias 5d, as shown in FIG. 13C. The lateral electrodes 5c or the through vias 5d are the same as those explained in Embodiment 3.

A chip capacitor 13 is a capacitive element which is mounted on the front surface of each of the dielectric substrates 5, and which electrically connects the electrode region 5e and one of the two electrode regions 5f. In addition, a chip capacitor 14 is a capacitive element which is mounted on the front surface of each of the dielectric substrates 5, and which electrically connects the electrode region 5e and the other one of the two electrode regions 5f. The chip capacitor 13 and the chip capacitor 14 are mounted on the front surface of each of the dielectric substrates 5, using, for example, a conductive substance such as a solder or an electrically conductive adhesive.

Output lead pins 4 and the electrode regions 5e of the dielectric substrate 5 are electrically connected by wires 7. The output terminals 3a of the TIA 3 and the electrode regions 5e of the dielectric substrates 5 are electrically connected by wires 8. The semiconductor light receiving element 2 and the input terminal 3b of the TIA 3 are electrically connected by a wire 9. Ground terminals 3c of the TIA 3 and the electrode regions 5f of each of the dielectric substrates 5 are electrically connected by wires 10.

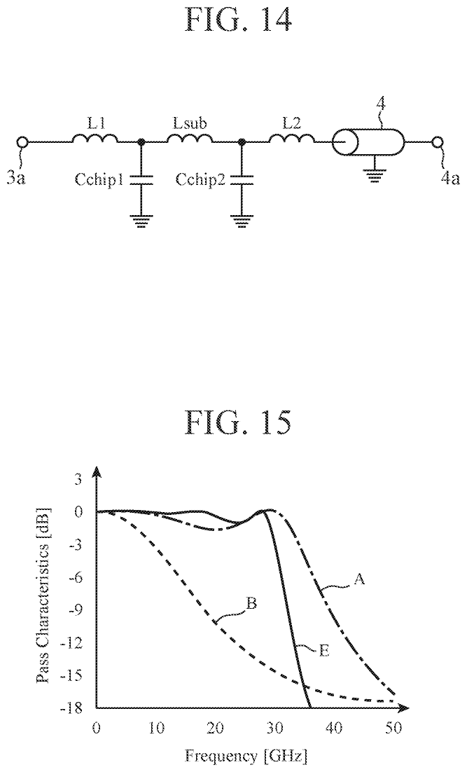

FIG. 14 is a diagram showing an equivalent circuit of the optical receiver module according to Embodiment 6, and shows the equivalent circuit of the optical receiver module shown in FIG. 13A. In the optical receiver module according to Embodiment 6, output signals of the TIA 3 are outputted, via the electrode regions 5e, to the output lead pins 4, and are outputted from lead pin outputs 4a.

Each chip capacitor 13 electrically connects an electrode region 5e and an electrode region 5f in the vicinity of a connection point with a wire 8, the connection point being in the electrode region 5e, and each chip capacitor 14 connects the electrode region 5e and another electrode region 5f in the vicinity of a connection point with a wire 7, the connection point being in the electrode region 5e. A capacitance C_{chip1} of each chip capacitor 13 occurs, and a capacitance C_{chip2} of each chip capacitor 14 occurs. That is, the optical receiver module according to Embodiment 6 has a structure in which one stage of low pass filter which includes an inductance and a capacitance is added, like the optical receiver module according to Embodiment 5.

FIG. 15 is a diagram showing simulation results of pass characteristics, and a simulation result of the optical receiver module according to Embodiment 1 is denoted by a reference sign A and a simulation result of a conventional optical receiver module is denoted by a reference sign B. In addition, a simulation result of the optical receiver module according to Embodiment 6 is denoted by a reference sign E. The conventional optical receiver module has the same structure as that shown in FIGS. 2A and 2B.

In the optical receiver module according to Embodiment 6, because the output signals of the TIA 3 are outputted to the output lead pins 4 after being transmitted via the dielectric substrates 5, the inductances L1 and L2 can be reduced. Further, because a low pass filter which includes an inductance and a capacitance is added, while in the simulation result E, peaking causes the pass band to be widened to close to the frequency of 30 GHz, an attenuation characteristic steeper than that in the simulation result A is provided in a high frequency band.

As mentioned above, in the optical receiver module according to Embodiment 6, the two electrode region 5f are electrically connected to the rear electrode 5B by the lateral electrodes 5c or the through vias 5d. One of the two electrode regions 5f and the electrode region 5e are electrically connected by a chip capacitor 13, and the other one of the two electrode regions 5f and the electrode region 5e are electrically connected by a chip capacitor 14. The output lead pins 4 and the electrode regions 5e are electrically connected by the wires 7, and the output terminals 3a of the TIA 3 and the electrode regions 5e are electrically connected by the wires 8. Because in the optical receiver module according to Embodiment 6 a low pass filter that includes an inductance and a capacitance is added, the band is improved, like in the case of any one of Embodiments 1 to 5. In addition, because an attenuation characteristic steeper than that of the optical receiver module according to Embodiment 1 is provided in a high frequency band, noises in the high frequency band can be eliminated.

### Embodiment 7

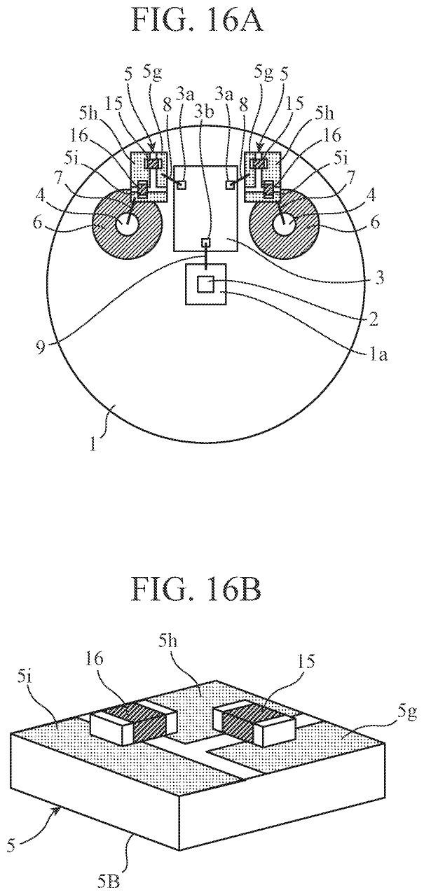

In an optical receiver module according to Embodiment 7, a front electrode of each of dielectric substrates 5 is divided into three electrode regions, and the electrode regions are electrically connected by inductive elements. FIG. 16A is a top view showing the structure of the optical receiver module according to Embodiment 7, and schematically shows a structure on a stem 1 with the cap of a CAN package removed. FIG. 16B is a perspective view showing a dielectric substrate 5 in Embodiment 6.

A TIA 3 in Embodiment 7 includes a pair of output terminals 3a and an input terminal 3b, as shown in FIG. 16A, and performs differential amplification on an electric signal inputted, via the input terminal 3b, from a semiconductor light receiving element 2, and outputs the amplified electric signals from the output terminals 3a. As shown in FIGS. 16A and 16B, an electrode region 5g, an electrode region 5h, and an electrode region 5i are disposed on a front surface (first surface) of each of the dielectric substrates 5, and a rear electrode (second electrode) 5B is disposed on the whole of a rear surface (second surface). The rear electrode 5B is grounded in a state where each of the dielectric substrates 5 is mounted on the stem 1. The electrode region 5g, the electrode region 5h, and the electrode region 5i are independent of one another.

A chip inductor 15 is an inductive element which is mounted on a front surface of each of the dielectric substrates 5, and which electrically connects the electrode region 5g and the electrode region 5h. A chip inductor 16 is an inductive element which is mounted on the front surface of each of the dielectric substrates 5, and electrically connects the electrode region 5h and the electrode region 5i.

The chip inductors 15 and 16 are mounted on the front surface of each of the dielectric substrates 5, using, for example, a conductive substance such as a solder or an electrically conductive adhesive.

Output lead pins 4 and the electrode regions 5i are electrically connected by wires 7 and the output terminals 3a of the TIA 3 and the electrode regions 5g are electrically connected by wires 8 in such a way that each of signal paths from the output terminals 3a of the TIA 3 to the output lead pins 4 passes through the chip inductors 15 and 16. In addition, the semiconductor light receiving element 2 and the input terminal 3b of the TIA 3 are electrically connected by a wire 9.

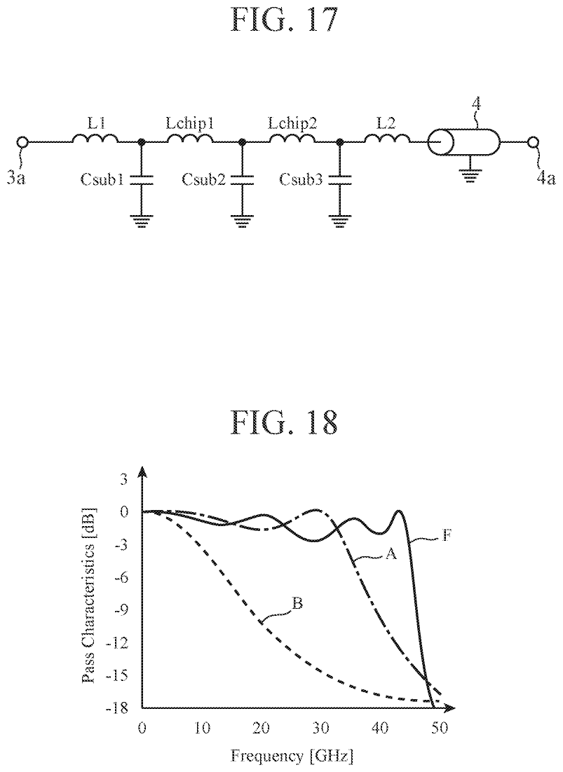

FIG. 17 is a diagram showing an equivalent circuit of an optical receiver module according to Embodiment 7, and shows the equivalent circuit of the optical receiver module shown in FIG. 16A. In the optical receiver module according to Embodiment 7, output signals of the TIA 3 are outputted, via the electrode regions 5g, the chip inductors 15, the electrode regions 5h, the chip inductors 16, and the electrode regions 5i, to the output lead pins 4, and are outputted from lead pin outputs 4a.

Between the output terminals 3a of the TIA 3 and the output lead pins 4, inductances L1 of the wires 8, inductances L_{chip1} of the chip inductors 15, inductances L_{chip2} of the chip inductors 16, and inductances L2 of the wires 7 occur, as shown in FIG. 17.

In each of the dielectric substrates 5, a capacitance C_{sub1} occurs between the electrode region 5g and the rear electrode 5B, a capacitance C_{sub2} occurs between the electrode region 5h and the rear electrode 5B, and a capacitance C_{sub3} occurs between the electrode region 5i and the rear electrode 5B. As mentioned above, the optical receiver module according to Embodiment 7 has a structure in which three stages of LC filter each of which includes an inductance and a capacitance are cascaded.

FIG. 18 is a diagram showing simulation results of pass characteristics, and a simulation result of the optical receiver module according to Embodiment 1 is denoted by a reference sign A and a simulation result of a conventional optical receiver module is denoted by a reference sign B. In addition, a simulation result of the optical receiver module according to Embodiment 7 is denoted by a reference sign F. The conventional optical receiver module has the same structure as that shown in FIGS. 2A and 2B.

In the optical receiver module according to Embodiment 7, because the output signals of the TIA 3 are outputted to the output lead pins 4 after being transmitted via the dielectric substrates 5, the inductances L1 and L2 can be reduced. Further, because the three stages of LC filter each of which includes an inductance and a capacitance are cascaded, the simulation result F shows that peaking causes the pass band to be widened to a high frequency band close to the frequency of 45 GHz, and an attenuation characteristic steeper than that in the simulation result A is provided in a high frequency band.

As mentioned above, in the optical receiver module according to Embodiment 7, the electrode region 5g and the electrode region 5h of each of the dielectric substrates 5 are electrically connected by a chip inductor 15, and the electrode region 5h and the electrode region 5i are electrically connected by a chip inductor 16. In addition, the output lead pins 4 and the electrode regions 5i are electrically connected by the wires 7, and the output terminals 3a of the TIA 3 and the electrode regions 5g are electrically connected by the wires 8. Cascading the three stages of low pass filter each of which includes an inductance and a capacitance provides a further improvement of the band and a steep attenuation characteristic of being able to eliminate noises in a high frequency band.

It is to be understood that the present disclosure is not limited to the above-mentioned embodiments, and any combination of two or more of the above-mentioned embodiments can be made, various changes can be made in any component according to any one of the above-mentioned embodiments, or any component according to any one of the above-mentioned embodiments can be omitted within the scope of the present disclosure.

### INDUSTRIAL APPLICABILITY

Because the optical receiver module according to the present disclosure can improve the band, the optical receiver module can be used for optical communication systems.

### REFERENCE SIGNS LIST

1, 100 stem, 1a, 100a submount, 2, 101 semiconductor light receiving element, 3a, 102a output terminal, 3b, 102b input terminal, 3c ground terminal, 4, 103 output lead pin, 4a, 103a lead pin output, 5 dielectric substrate, 5B rear electrode, 5a, 5b front electrode, 5a-1, 5a-2, 5e to 5i electrode region, 5c lateral electrode, 5d through via, 6, 104 sealing agent, 7 to 10, 105, 106 wire, 11, 13, 14 chip capacitor, and 12, 15, 16 chip inductor.

1. An optical receiver module comprising:
a stem;
a semiconductor light receiving element to convert a light signal into an electric signal;
a transimpedance amplifier to amplify the electric signal;
a pair of output lead pins via which differential output signals of the transimpedance amplifier are taken to outside the stem;
dielectric substrates disposed between output terminals of the transimpedance amplifier and the output lead pins; and
first electrodes disposed on first surfaces of the dielectric substrates,
wherein the output terminals of the transimpedance amplifier and the first electrodes are electrically connected by wires,
the output lead pins and the first electrodes are electrically connected by wires, and
the output signals of the transimpedance amplifier are outputted, via the dielectric substrates, to the output lead pins,
wherein the optical receiver module further comprises second electrodes disposed on second surfaces opposite to the first surfaces of the dielectric substrates,
each of the first electrodes is divided into multiple electrode regions,
one of the multiple electrode regions is electrically connected to one of the second electrodes by a through via or a lateral electrode, and
the electrode region electrically connected to the one of the second electrodes and a ground terminal of the transimpedance amplifier are electrically connected by a wire.

2. An optical receiver module comprising:
a stem;
a semiconductor light receiving element to convert a light signal into an electric signal;
a transimpedance amplifier to amplify the electric signal;
a pair of output lead pins via which differential output signals of the transimpedance amplifier are taken to outside the stem;
dielectric substrates disposed between output terminals of the transimpedance amplifier and the output lead pins; and
first electrodes disposed on first surfaces of the dielectric substrates,
wherein the output terminals of the transimpedance amplifier and the first electrodes are electrically connected by wires,
the output lead pins and the first electrodes are electrically connected by wires, and
the output signals of the transimpedance amplifier are outputted, via the dielectric substrates, to the output lead pins,
wherein the optical receiver module further comprises second electrodes disposed on second surfaces opposite to the first surfaces of the dielectric substrates,
wherein each of the first electrodes is divided into multiple electrode regions,
one of the multiple electrode regions is electrically connected to one of the second electrodes by a through via or a lateral electrode, and
the one of the multiple electrode regions and another electrode region out of the multiple electrode regions are electrically connected by a capacitive element disposed on each of the dielectric substrates.

3. An optical receiver module comprising:
a stem;
a semiconductor light receiving element to convert a light signal into an electric signal;
a transimpedance amplifier to amplify the electric signal;
a pair of output lead pins via which differential output signals of the transimpedance amplifier are taken to outside the stem;
dielectric substrates disposed between output terminals of the transimpedance amplifier and the output lead pins; and
first electrodes disposed on first surfaces of the dielectric substrates,
wherein the output terminals of the transimpedance amplifier and the first electrodes are electrically connected by wires,
the output lead pins and the first electrodes are electrically connected by wires,
the output signals of the transimpedance amplifier are outputted, via the dielectric substrates, to the output lead pins, and
each of the first electrodes is divided into multiple electrode regions, and
the optical receiver module further comprises inductive elements disposed on the first surfaces of the dielectric substrates for electrically connecting between the electrode regions,
wherein the output terminals of the transimpedance amplifier and the electrode regions are electrically connected by wires, and the output lead pins and the electrode regions are electrically connected by wires such that signal paths from the output terminals of the transimpedance amplifier to the output lead pins pass the inductive elements.

4. The optical receiver module according to claim 1, wherein impedance of each of the first electrodes is 50Ω.

5. The optical receiver module according to claim 1, wherein the semiconductor light receiving element is a photodiode.

6. The optical receiver module according to claim 1, wherein the semiconductor light receiving element is an avalanche photodiode.

7. The optical receiver module according to claim 1, wherein the semiconductor light receiving element is a flip-chip-mounted photodiode of a backside incidence type.

8. The optical receiver module according to claim 1, wherein the semiconductor light receiving element is a flip-chip-mounted avalanche photodiode of a backside incidence type.
